(19) United States
(12) Patent Application Publication
(10) Pub. No.: US 2002/0132139 A1
(43) Pub. Date: Sep. 19, 2002

(54) Magnetic recording medium having improved overwrite and SNR characteristics

(76) Inventors: Jack Jyh-Kau Chang, Hsin-Chu City (TW); Yi-Hong Huang, Chung-Ho City (TW); Wu-Sun Wang, Hsin-Chu City (TW); Chun-Lee Liang, Hsin-Chu City (TW); I-An Chen, Chung-Ho City (TW); Lu-Mei Liang, Chu-Nan Town (TW)

Correspondence Address: NAIPO (NORTH AMERICA INTERNATIONAL PATENT OFFICE), P.O. BOX 506, MERRIFIELD, VA, 22116, US

(21) Appl. No.: 09/754,194

(22) Filed: Jan. 5, 2001

(51) Int. Cl. G11B 5/66; B32B 15/00; C23C 14/34; B32B 15/04; H01F 1/01; H01F 10/12

(52) U.S. Cl. 428/694 TM; 428/694 TS; 204/192.2

(57) ABSTRACT

A magnetic recording medium having a dual magnetic structure layer for the separate control of KuV/kT and SNR to achieve high SNR, increased overwrite (OW) capability and good thermal stability. The magnetic recording medium includes a nonmagnetic Al—Mg substrate followed by the addition of a NiP layer electrolessly plated on the surface of the substrate. A dual-film magnetic layer is formed on the substrate. The dual-film magnetic structure comprises an upper first magnetic film of CoCrPtB alloy and a lower second magnetic film of a CoCrPtTaB alloy. The composition and thickness of each magnetic film in the dual-film magnetic structure allows for the simultaneous ability of the magnetic recording medium to obtain high SNR, increased OW capability and good thermal stability to improve the overall performance of the media.

### BACKGROUND OF THE INVENTION

1. Field of the Invention

The present invention relates to a magnetic recording medium, and more particularly, to a magnetic recording medium with improved overwrite and SNR characteristics.

2. Description of the Prior Art

Magnetic recording mediums are used in hard disk drives and function in recording and storing large amounts of data. Typically, a magnetic recording medium is made up of a substrate, underlying layers and a magnetic layer, respectively. More specifically, a nonmagnetic substrate (glass, ceramic, glass-ceramic composite, Al, or Al—Mg alloy) is used for the deposition of the underlying layers andmagnetic layer. A seed layer is first sputtered onto the substrate followed by the formation of a nonmagnetic, Cr-based underlayer. Next, a magnetic layer, composed of a Co-based magnetic thin film, is deposited on the underlayer.

The magnetic layer is composed of a magnetic thin film used to increase storage density. The storage density of a magnetic recording medium is dependent on both the crystallographic arrangement and the microstructure of the magnetic thin film which are determined by the materials used for the magnetic thin film as well as the properties of the underlying layers. Factors affecting storage density are defined below:

(a) Coercivity (Hc): the magnetic field required to reduce remanence magnetic flux to zero. A higher coercivity is associated with a higher information storage density by allowing adjacent recording bits to be more closely placed without mutual cancellation. Most materials used in the present have a Hc greater than 2200 Oersteds (Oe).

(b) Signal-to-Noise Ratio (SNR): defined as 20*log [Signal Voltage/Noise Voltage]. A high SNR is associated with a high bit density to be read with a given degree of reliability since more signals can be detected in a low noise reading operation setting.

(c) Overwrite capability (Ow): defined as 20*log [Residual LFTAA/Original LFTAA] and is the effectiveness of erasing a signal read at one frequency by a higher frequency signal and provides a measure of a remaining residual signal after the old signal is overwritten by a new signal. The more negative the value of Ow the better the overwrite capability. Generally, the value is required to be less than −26 dB.

(d) Thermal stability (KuV/kT): V is the switching volume of magnetic moments. Ku is the magnetic anisotropic constant, which determines the required energy per unit volume to deviate the magnetic moment from its preferred orientation. The total energy for a magnetic moment with a volume of V deviated from its preferred orientation by a angle of θ is given by: E=KuV sin² θ. K is Boltzman constant. T is absolute temperature. KT represents thermal energy. Therefore, the magnetic media with higher KuV/kT means that thermal energy is less likely to disturb the direction of magnetic moments, and thus the media is more thermally stable.

As mentioned, the magnetic properties of the magnetic layer is dependent not only on the materials used in its formation, but also the properties of the underlying layers. Thus, the use of an underlayer with a crystalline structure closely matching that of the magnetic layer is essential in reducing lattice mismatch to increase coercivity and SNR and consequently, improving the overall magnetic recording performance.

Recent prior art have also mentioned the use of a dual-film magnetic structure in the magnetic recording medium to improve both media noise and coercivity. In U.S. Pat. No. 5,772,857, Zhang mentions the deposition of a bi-layer magnetic film over a substrate whereby the double layer film produces magnetic media with higher coercivity and lower media noise in comparison with a single layer film. However, Zhang does not mention the dual-film structure as functioning to improve either thermal stability (KuV/kT) or overwrite (OW) capability.

### SUMMARY OF THE INVENTION

It is therefore a primary objective of the present invention to produce a magnetic recording medium with high SNR, improved overwrite (OW) capability and good thermal stability (KuV/kT).

In brief summarization, the present invention provides a magnetic recording medium used in a hard disk drive. A nonmagnetic NiP/Al—Mg substrate is used for the deposition of a Cr seed layer, a Cr-based alloy underlayer, a CoCr intermediate layer, a dual-film magnetic layer and a diamond-like carbon (protective) overcoat, respectively, on the substrate. The dual-film magnetic layer comprises an upper first magnetic film and a lower second magnetic film with characteristics allowing for the simultaneous improvement of SNR, thermal stability and OW capability. The first magnetic film is composed of a CoCrPtB alloy while the second magnetic layer is composed of a CoCrPtTaB alloy, a CoCrPtTa alloy, a CoCrTa alloy, or a CoCrPtTaNb alloy.

It is an advantage of the present invention that the magnetic recording medium has a dual magnetic layer structure to separately control KuV/kT and SNR to achieve media with high SNR, improved overwrite (OW) and good thermal stability.

These and other objectives of the present invention will no doubt become obvious to those of ordinary skill in the art after having read the following detailed description of the preferred embodiment illustrated in the various figures and drawings.

### BRIEF DESCRIPTION OF THE DRAWINGS

FIG. 1 is a cross-sectional diagram of the structure of a magnetic recording medium according to the present invention.

Table 1 lists the KuV/kT, SNR and OW of a dual and single magnetic layer structure.

FIG. 2 illustrates a CoCrPtTaB/total magnetic layer thickness ratio effect on KuV/kT.

FIG. 3 illustrates a CoCrPtTaB/total magnetic layer thickness ratio effect on SNR.

### DETAILED DESCRIPTION OF THE PREFERRED EMBODIMENT

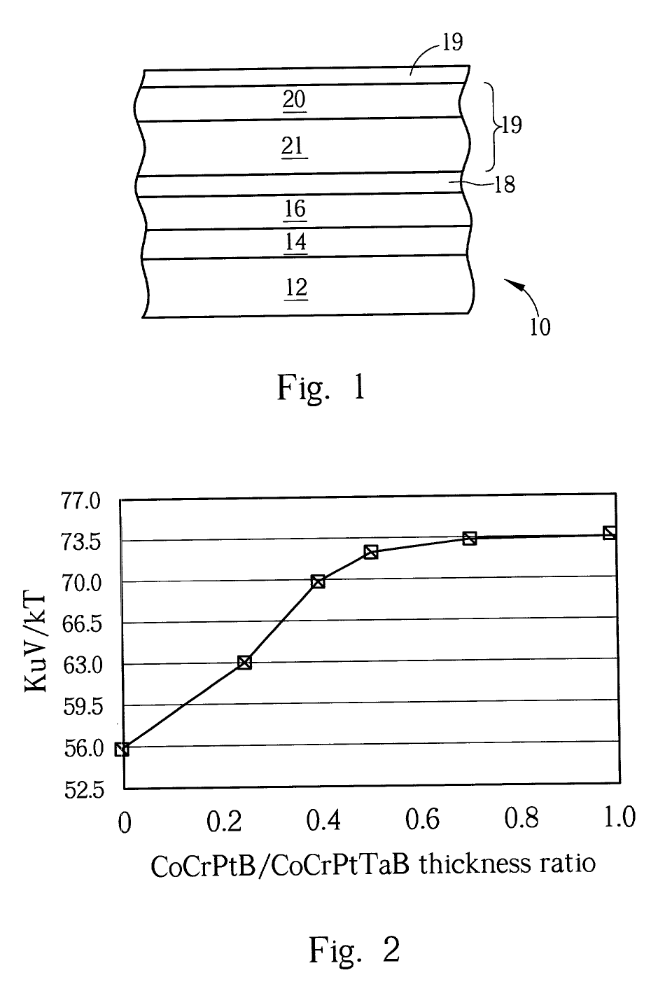

Please refer to FIG. 1. FIG. 1 is a cross-sectional diagram of the structure of a magnetic recording medium 10 according to the present invention. The magnetic recording medium 10 has a nonmagnetic substrate 12 of Al—Mg, electrolessly plated with a NiP layer (not shown) to enhance rigidity and reduce roughness of the substrate surface. The substrate 12 can also be formed of Al, an Al—Mg alloy, glass, ceramic, or a glass ceramic composite. A Cr seed layer 14, and an underlayer 16, are then sputtered on the substrate 12, respectively. The underlayer 16 is composed of a CrMo alloy but can be replaced by a Cr-based alloy containing vanadium, tungsten, or ruthenium. A dual-film magnetic layer 19, with a hexagonal-closed pack (hcp) crystalline structure, is then sputtered on the underlayer 16.

The dual-film magnetic layer 19 comprises an upper first magnetic film 20 and a lower second magnetic film 21; the first magnetic film 20 is composed of a CoCrPtB alloy while the second magnetic film is composed of a CoCrPtTaB alloy, a CoCrPtTa alloy, a CoCrTa alloy, or a CoCrPtTaNb alloy. The addition of a hcp CoCr alloy intermediate layer 18 is interposed between the body cubic center (bcc) underlayer 16 and the hcp structure of the dual-film magnetic layer 19 to reduce lattice mismatching. Finally, a diamond-like carbon (DLC) overcoat 22 with a thickness less than 100 angstroms is formed on the upper first magnetic film 20 of the dual-film magnetic layer 19 to protect the magnetic layer 19 against damage during use.

In the present invention, variation in the composition and thickness of the two magnetic films 20, 21 increases thermal stability (KuV/kT) to improve OW capability while simultaneously maintaining a high SNR. In the following Table 1, it illustrates the KuV/kT, SNR and OW of both dual and single magnetic layer structures. In addition, comparative measurements of remanence (Mrt) and coercivity (Hc) are also shown.

| Film Structure | Mrt | Hc | OW | SNR | KuV/kT |
|---|---|---|---|---|---|
| CoCrPtB | 0.33 | 3100 | 20 | 4.0 | 56 |
| CoCrPtTaB | 0.33 | 3050 | 37 | 1.5 | 73 |
| CoCrPtTaB/CoCrPtB | 0.33 | 3080 | 25 | 3.5 | 60 |
| (top) (bottom) | | | | | |
| CoCrPtB/CoCrPtTaB | 0.33 | 3120 | 35 | 3.8 | 70 |
| (top) (bottom) | | | | | |

The above table shows an overall improvement in KuV/kT, OW and SNR of a dual magnetic layer structure versus a single magnetic structure layer. However, the greatest SNR value is seen in the CoCrPtB single magnetic layer. Thus, the CoCrPtB layer has a composition suitable for low media noise. As well, the greatest KuV/kT value, and consequently OW value, are seen in the CoCrPtTaB single magnetic layer. Thus, the CoCrPtTaB layer has a composition suitable for good thermal stability.

Therefore, the dual magnetic structure layer 19 comprised of the upper first magnetic film 20 of CoCrPtB and the lower second magnetic film 21 of CoCrPtTaB optimizes the overall performance of a magnetic recording medium as determined by KuV/kT, SNR and OW whereby the first magnetic film 20 has a first KuV/kT value and the second magnetic film 21 has a second KuV/kT value, greater than the first KuV/kT value. Also, the first magnetic film 20 has a first media noise and the second magnetic film 21 has a second media noise, greater than the first media noise.

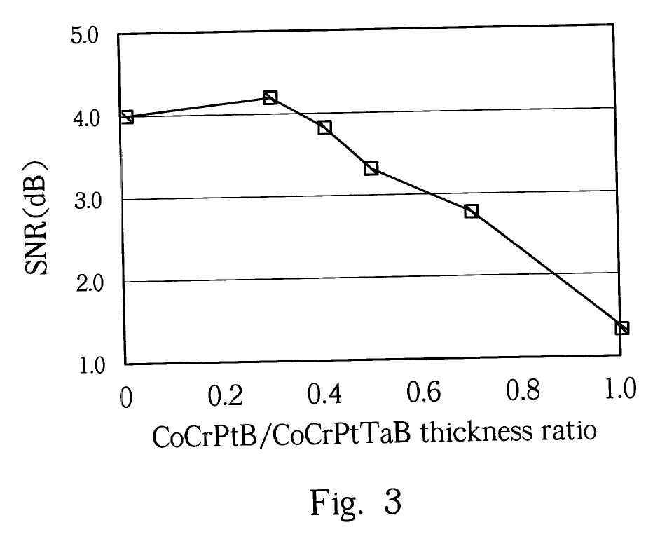

However, as shown in FIG. 2 and FIG. 3, achievement of both the optimal KuV/kT value and SNR value, respectively, of Table 1 are dependent on the thickness ratio of the lower second magnetic film (CoCrPtTaB) 20 to the total thickness of the dual-film magnetic layer 19. Thus, a thickness ratio of the second magnetic film 20 to the total thickness of the dual-film magnetic layer 19 between 0.3 and 0.7, preferably 0.5, produces both high KuV/kT and SNR values. In addition, the CoCrPtTaB alloy of the second magnetic film 21 can be replaced by a CoCrPtTa alloy or a CoCrTa alloy.

Those skilled in the art will readily observe that numerous modifications and alterations of the device may be made while retaining the teachings of the invention. Accordingly, the above disclosure should be construed as limited by the metes and bounds of the appended claims.

What is claimed is:

1. A magnetic recording medium used in a hard disk drive comprising:
a nonmagnetic substrate;
a seed layer sputtered on the nonmagnetic substrate;
an underlayer sputtered on the seed layer;
a dual-film magnetic layer for recording information formed over the underlayer, the dual-film magnetic layer comprising an upper first magnetic film having a first KuV/kT value, and a lower second magnetic film having a second KuV/kT value which is greater than the first KuV/kT value so that the magnetic recording medium displays a superior overwrite capability and, at the same time, maintains a high SNR provided by the first magnetic film;
wherein the ratio of the thickness of the lower second magnetic film to the total thickness of the dual-film magnetic layer ranges from 0.3 to 0.7.

2. The magnetic recording medium of claim 1 wherein the nonmagnetic substrate is composed of Al, an Al—Mg alloy, glass, ceramic, or a glass-ceramic composite.

3. The magnetic recording medium of claim 1 wherein the substrate is an aluminum-magnesium substrate and an electrolessly plated NiP layer is further disposed on the surface of the Al—Mg substrate for enhancing the rigidity of the substrate and for reducing the roughness of the surface of the substrate.

4. The magnetic recording medium of claim 1 wherein the magnetic recording medium further comprises an intermediate layer with a hcp (hexagonal-closed-packed) crystalline structure interposed between the underlayer and the dual-film magnetic layer for improving lattice matching.

5. The magnetic recording medium of claim 4 wherein the intermediate layer is composed of a CoCr alloy.

6. The magnetic recording medium of claim 1 wherein the ratio of the thickness of the first magnetic film to the total thickness of the dual-film magnetic layer is about 0.5.

7. The magnetic recording medium of claim 1 wherein the first magnetic film has a first media noise, and the second magnetic film has a second media noise that is greater than the first media noise.

8. The magnetic recording medium of claim 1 wherein the first magnetic film is composed of a CoCrPtB alloy.

9. The magnetic recording medium of claim 1 wherein the second magnetic film is composed of a CoCrPtTaB alloy, a CoCrPtTa alloy, a CoCrTa alloy, or a CoCrPtTaNb alloy.

10. The magnetic recording medium of claim 1 wherein the seed layer is composed of chromium.

11. The magnetic recording medium of claim 1 wherein the underlayer is composed of Cr-based alloy containing vanadium, molybdenum, tungsten, or ruthenium.

12. The magnetic recording medium of claim 11 wherein the underlayer is composed of a CrMo alloy.

13. The magnetic recording medium of claim 1 further comprising a diamond-like carbon (DLC) overcoat formed on the upper first magnetic film of the dual-film magnetic layer.

14. The magnetic recording medium of claim 13 wherein the thickness of the DLC overcoat is less than 100 Å.
